(19) United States
(12) Patent Application Publication
(10) Pub. No.: US 2020/0365445 A1
(43) Pub. Date: Nov. 19, 2020

(54) SUSCEPTOR AND METHOD OF MANUFACTURING SEMICONDUCTOR DEVICE

(71) Applicant: SUMITOMO ELECTRIC INDUSTRIES, LTD., Osaka (JP)

(72) Inventors: Takehiko KIKUCHI, Osaka (JP); Nobuhiko NISHIYAMA, Tokyou (JP)

(73) Assignee: SUMITOMO ELECTRIC INDUSTRIES, LTD., Osaka (JP)

(21) Appl. No.: 16/859,128

(22) Filed: Apr. 27, 2020

(30) Foreign Application Priority Data
May 15, 2019 (JP) 2019-092201

(51) Int. Cl. H01L 21/687; H01L 33/00; H01L 33/58; H01L 23/544

(52) U.S. Cl. CPC H01L 21/68785; H01L 33/0095; H01L 33/58; H01L 2223/54426; H01L 2933/0058; H01L 2223/5442; H01L 23/544

(57) ABSTRACT

A susceptor includes a first metal plate and a second metal plate bonded to a surface of the first metal plate. The second metal plate has a plurality of first openings. The surface of the first metal plate is exposed from the plurality of first openings.

### CROSS-REFERENCE TO RELATED APPLICATION

This application is based upon and claims the benefit of priority of the prior Japanese Patent Application No. 2019-092201, filed on May 15, 2019, the entire contents of which are incorporated herein by reference.

### FIELD

The present invention relates to a susceptor and a method of manufacturing a semiconductor device.

### BACKGROUND

A technique for manufacturing a semiconductor device by bonding a chip including a light emitting element or the like obtained from a compound semiconductor substrate with a silicon wafer on which a waveguide is formed has been known (for example, see Xianshu. Luo et al. frontiers in MATERIALS Vol. 2, No. 28, 2015).

### SUMMARY

The chips of the compound semiconductor are temporarily bonded to the flat supporting substrate with an adhesive or the like, the supporting substrate and the silicon wafer are opposed to each other, and the adhesive is removed, whereby the chips are transferred to the silicon wafer. The adhesive may stick to the interface between the chip and the silicon wafer, and the semiconductor device may be contaminated.

A susceptor with a plurality of recesses may be used instead of the flat supporting substrate. The chip is placed in a recess in the susceptor without using any adhesive. Then, the chip is transferred from the susceptor to the silicon wafer. Since the adhesive is not used, contamination is also suppressed. However, if the depth of the recesses varies, the height of the susceptor also becomes uneven, and the yield of bonding decreases. It is therefore an object of the present disclosure to provide a susceptor capable of reducing variation in the height of chips, and a method of manufacturing a semiconductor device using the susceptor.

The present disclosure provides a susceptor including a first metal plate and a second metal plate bonded to a surface of the first metal plate. The second metal plate has a plurality of first openings, and the surface of the first metal plate exposed from the plurality of first openings.

The present disclosure provides a method for manufacturing a semiconductor device including the steps of: forming an epitaxial substrate by growing a plurality of compound semiconductor layers on a compound semiconductor substrate; forming a chip from the epitaxial substrate by dividing the epitaxial substrate; arranging the chip in one of the first openings of the susceptor; preparing a first substrate containing silicon, the first substrate having a waveguide mesa; and causing the susceptor and the first substrate to face each other and bonding the chip to the first substrate.

### BRIEF DESCRIPTION OF THE DRAWINGS

FIG. 1A is a plan view illustrating a susceptor according to an embodiment.

FIG. 1B is a cross-sectional view illustrating a susceptor.

FIG. 2A is a plan view illustrating a metal plate.

FIG. 2B is a plan view illustrating a metal plate.

FIG. 3A is a perspective view illustrating a semiconductor device.

FIG. 3B is a cross-sectional view illustrating a semiconductor device.

FIG. 4A is a plan view illustrating a manufacturing process of a semiconductor device.

FIG. 4B is a cross-sectional view illustrating a process for manufacturing a semiconductor device.

FIG. 5 is a plan view illustrating a manner of manufacturing a semiconductor device.

FIG. 6A is a perspective view illustrating a manufacturing process of a semiconductor device.

FIG. 6B is a cross-sectional view illustrating a method for manufacturing a semiconductor device.

FIG. 6C is a cross-sectional view illustrating a method for manufacturing a semiconductor device.

FIG. 7A is a cross-sectional view illustrating a method for manufacturing a semiconductor device.

FIG. 7B is a cross-sectional view illustrating a process for manufacturing a semiconductor device.

FIG. 7C is a perspective view illustrating a manufacturing process of a semiconductor device.

FIG. 8A is a plan view illustrating a susceptor according to an embodiment.

FIG. 8B is an enlarged view of a mark.

FIG. 8C is an enlarged view of a mark.

FIG. 9 is a plan view illustrating a susceptor according to an embodiment.

FIG. 10 is a cross-sectional view illustrating a susceptor according to an embodiment.

FIG. 11A is a plan view illustrating a metal plate.

FIG. 11B is a plan view illustrating a metal plate.

FIG. 12A is a plan view illustrating a metal plate.

FIG. 12B is a plan view illustrating a metal plate.

### DESCRIPTION OF EMBODIMENTS

First, the contents of the embodiment of the present invention will be described by enumerating.

In an embodiment, (1) a susceptor includes a first metal plate and a second metal plate bonded to a surface of the first metal plate. The second metal plate has a plurality of first openings, and the surface of the first metal plate is exposed from the plurality of first openings. The first metal plate and the second metal plate can be processed with high accuracy, and variations in thickness of the first metal plate is suppressed. The variation in the heights of the chips are reduced.

(2) The first metal plate and the second metal plate may be joined by metal diffusion bonding. Since the adhesive is not used, contamination caused by the adhesive is suppressed.
(3) The first metal plate and the second metal plate may be stainless steel plates. Since stainless steel can be processed with high accuracy, variation in thickness is suppressed. Therefore, the variation in the heights of the chips is reduced.
(4) Thickness variation of the first metal plate may be 0.010 mm or less. Variations in the height of the chips can be effectively reduced.
(5) The second metal plate may have a mark on a surface opposite to the bonding surface with the first metal plate. By using the marks for alignment, alignment of the susceptor can be performed with high accuracy.
(6) The second metal plate may have a plurality of second openings, each of which is continuous with each of the plurality of first openings. The placement of the chips can be facilitated.
(7) The first metal plate may have a plurality of third openings at positions overlapping with the plurality of first openings. By sucking the first opening through the third opening, the chip can be adsorbed and fixed in the susceptor.
(8) A method of manufacturing a semiconductor device includes a step of forming an epitaxial substrate by growing a plurality of compound semiconductor layers on a compound semiconductor substrate; a step of forming a chip from the epitaxial substrate by dividing the epitaxial substrate; a step of arranging the chip in one of the first openings of the susceptor; a step of preparing a first substrate containing silicon, the first substrate having a waveguide mesa; and a step of bonding the chip to the first substrate by causing the susceptor and the first substrate to face each other. By using the susceptor made by the first metal plate, the bonding can be processed with high accuracy, since variations in thickness of the first metal plate is small. Therefore, the variation in the heights of the chips can be reduced.

### Details of Embodiments of the Invention

Specific examples of a susceptor and a method for manufacturing a semiconductor device according to an embodiment of the present invention will be described below with reference to the drawings. It should be noted that the present invention is not limited to these examples, but is indicated by the claims, and it is intended to include all modifications within the meaning and range equivalent to the claims.

### First Embodiment

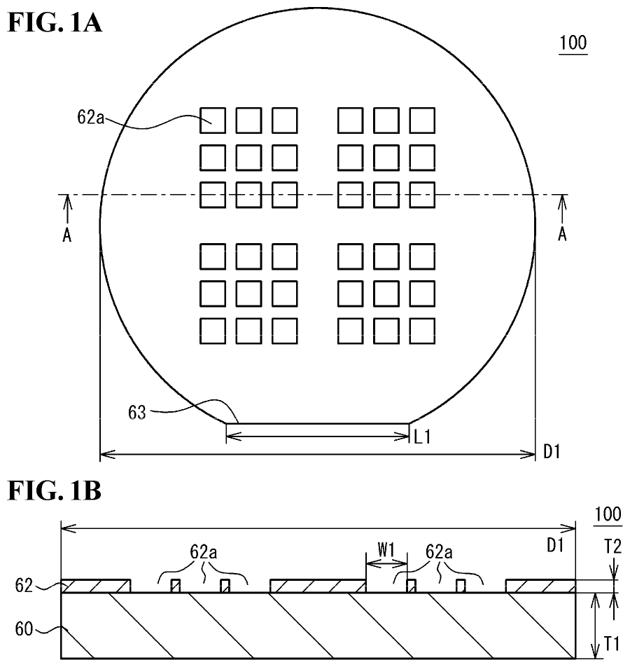

(Susceptor) FIG. 1A is a plan view illustrating a susceptor 100 according to the first embodiment. FIG. 1B is a cross-sectional view illustrating the susceptor 100 and illustrates a cross-section taken along line A-A of FIG. 1A.

As illustrated in FIG. 1A, the susceptor 100 is, for example, a circular metallic plate. The susceptor 100 has an orientation flat 63 and a plurality of openings 62a (first openings). The opening 62a is, for example, square. The width W1 of the opening 62a is, for example, 2.2 mm. The distance between the adjacent openings 62a is, for example, 2 mm. In FIG. 1A, the number of the openings 62a is 36, but may be 36 or more or less than 36. The diameter D1 of the susceptor 100 is, for example, 50 mm. The length L1 of the orientation flat 63 is, for example, 16 mm.

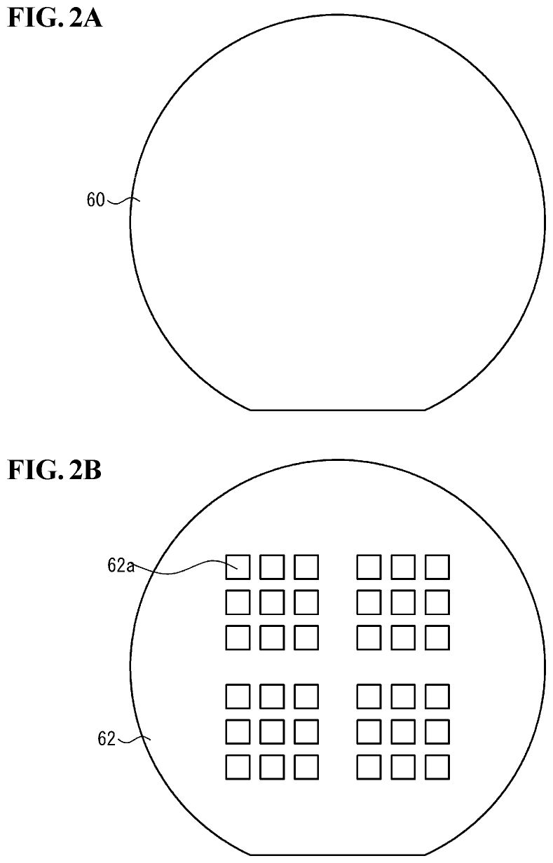

As illustrated in FIG. 1B, the susceptor 100 includes a metal plate 60 (first metal plate) and a metal plate 62 (second metal plate). FIG. 2A is a plan view illustrating the metal plate 60, and FIG. 2B is a plan view illustrating the metal plate 62. The metal plates 60 and 62 have the same circumferential shape in the plan view. The metal plates 60 and 62 are made of stainless-steel such as SUS316L (regulated by Japanese Industrial Standards), for example. One face of the metal plate 60 and one face of the metal plate 62 are joined by, for example, metal diffusion bonding. Each of the opening 62a penetrates the metal plate 62, and penetrate the metal plate 62 in the thickness direction. The metal plate 60 is exposed in the opening 62a. The thickness T1 of the metal plate 60 is, for example, 0.5 mm, and the thickness T2 of the metal plate 62 is, for example, 0.2 mm. In-plane variations of the thicknesses T1 and T2 are, for example, 0.003 mm.

(Manufacturing method of susceptor) As illustrated in FIG. 2A, the metal plate 60 is formed from a stainless-steel plate. The surface of the metal plate 60 is polished to have a thickness T1 of 0.5 mm±0.003 mm. As illustrated in FIG. 2B, the metal plate 62 is formed from a stainless-steel plate. A plurality of openings 62a are formed in the metal plate 62 by a photoetching method or the like. The opening 62a penetrates the metal plate 62. The surface of the metal plate 62 is polished to a thickness T2 of 0.2 mm±0.003 mm. The surfaces of the metal plates 60 and 62 are polished to flatten them. The flat faces are brought into contact with each other and bonded by metal diffusion bonding without using an adhesive or the like. Thus, the susceptor 100 is formed.

The opening 62a of the metal plate 62 and the surface of the metal plate 60 form a recess of the susceptor 100. A chip for bonding is mounted in the recess of the susceptor 100. In the susceptor 100, the surface of the metal plate 60 polished with high precision becomes the bottom surface of the recess. The bottom surface is formed from a top surface of the metal plate 60. The top surface of the metal plate 60 is formed by polishing when the metal plate 60 has a plate-like shape. The bottom surface of the recess of the susceptor 100 is a high-precision surface with less irregularity compared to a bottom surface of a recess formed by grinding such as the countersinking. Thus, the height variation of the upper surfaces of the chips mounted on the bottom surface of the recess of the susceptor 100 is reduced.

The opening 62a of the metal plate 62 is penetrated when the metal plate 62 has a plate-like shape. The accuracy of the width of the opening 62a is higher than that of the opening of the recess formed by the countersinking process. An appropriate clearance can be provided between a side surface of the recess and the chip, when the chip is mounted in the recess.

The susceptor 100 is manufactured by metal diffusion bonding of the metal plate 60 and the metal plate 62. Since no adhesive is used in the manufacture of the susceptor 100, the adhesive does not contaminate the chips.

(Semiconductor Devices)

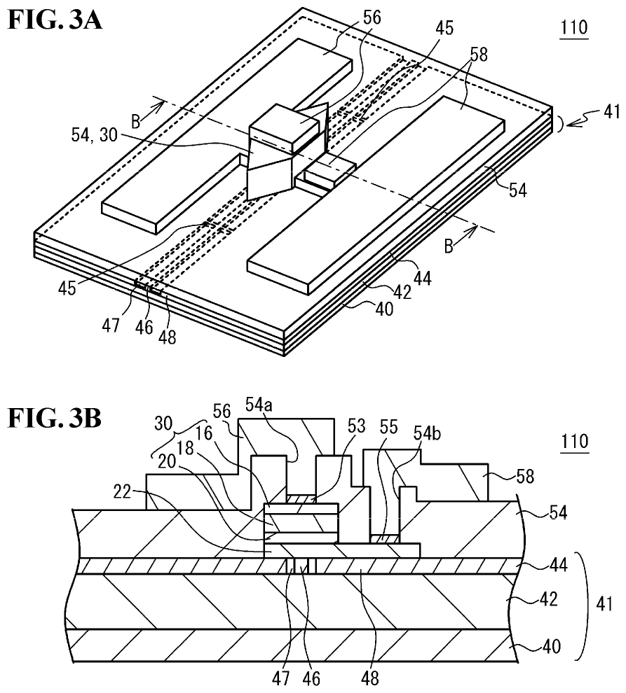

Next, a semiconductor device manufactured using the susceptor 100 will be described. FIG. 3A is a perspective view illustrating a semiconductor device 110, and FIG. 3B is a cross-sectional view illustrating the semiconductor device 110, and illustrates a cross-section along the line B-B of FIG. 3A. As illustrated in FIG. 3A and FIG. 3B, the semiconductor device 110 includes a substrate 40, a silicon dioxide (SiO₂) layer 42, a silicon (Si) layer 44, a compound semiconductor mesa 30, an insulating film 54, p-type wirings 56, and n-type wirings 58.

The Si substrate 40, the SiO₂ layer 42 and the Si layer 44 form a silicon-on-insulator (SOI) substrate 41. The Si layer 44 is provided with a wall 45, a waveguide mesa 46, a groove 47, and a terrace 48.

As illustrated in FIG. 3A, the mesa 30 is tapered at both ends. As illustrated in FIG. 3B, the mesa 30 includes a p-type contact layer 16, a p-type cladding layer 18, and an active layer 20. The tip of the mesa 30 overlies the waveguide mesa 46. An n-type contact layer 22 is provided between the active layer 20 and the Si layer 44. As will be described later, the SOI substrate 41 and a chip of the compound semiconductor including the active layer 20 are bonded to form the semiconductor device 110.

The insulating film 54 covers the Si layer 44, the n-type contact layer 22, and the mesa 30. The insulating film 54 has an opening 54a on the mesa 30 and an opening 54b on the n-type contact layer 22. A p-type electrode 53 is provided in the opening 54a and on the upper face of the p-type contact layer 16. The p-type wiring 56 is provided from the inside of the opening 54a to the upper face of the insulating film 54, and the p-type wiring 56 contacts the p-type electrode 53.

An n-type electrode 55 is provided in the opening 54b and on the upper face of the n-type contact layer 22. The n-type wiring 58 is provided from the inside of the opening 54b to the upper face of the insulating film 54, and the n-type wiring 58 contacts the n-type electrode 55.

The semiconductor device 110 functions as a hybrid laser. In the semiconductor device 110, the mesa 30 which is an active element and the waveguide mesa 46 of the SOI substrate which is a passive element are bonded to each other to be evanescently optically coupled. Spontaneous emission light having a wavelength distribution centered at, for example, 1.55 μm is emitted from the active layer 20, output from the tip of the mesa 30, and propagates through the waveguide mesa 46. By providing a wavelength-selective light reflecting device such as a ring resonator or a DBR (Distributed Bragg Reflector) so as to sandwich the active layer 20, only light having a wavelength of 1.55 μm resonates inside the active layer 20, and the laser light is emitted from the semiconductor device 110 as laser light.

(Procedure of Manufacturing a Semiconductor Device)

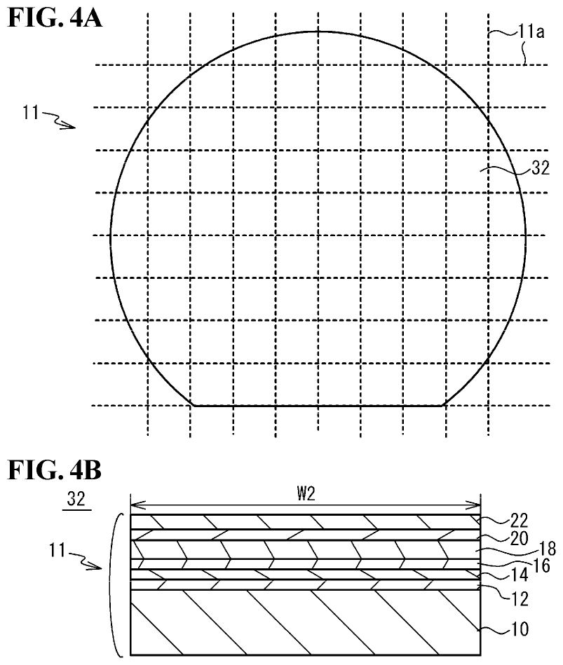

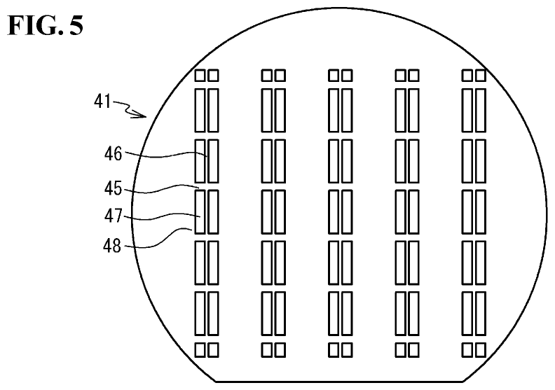

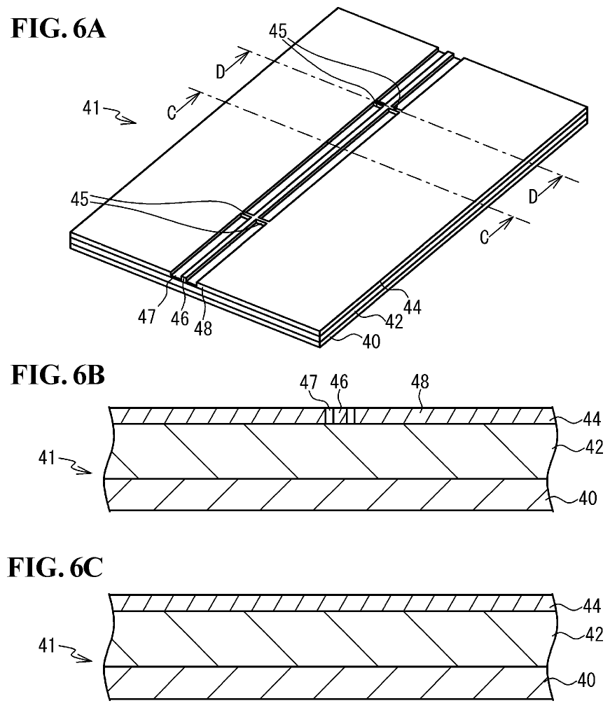

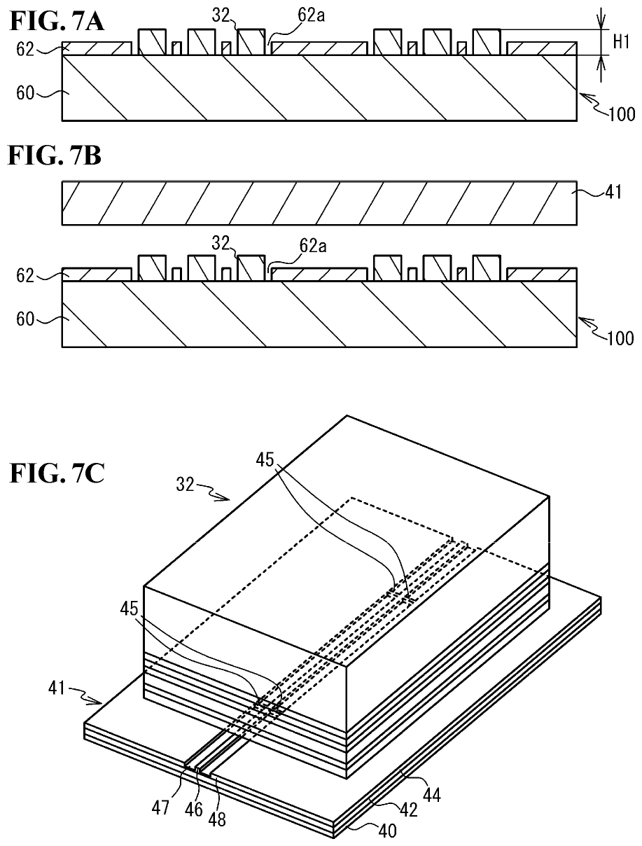

FIG. 4A and FIG. 5 are plan views illustrating methods of manufacturing the semiconductor device 110. FIG. 4B and FIG. 6B to FIG. 7B are cross-sectional views illustrating methods of manufacturing the semiconductor device 110. FIG. 6A and FIG. 7C are perspective views illustrating methods of manufacturing the semiconductor device 110.

(Compound Semiconductor Chips)

FIG. 4A and FIG. 4B illustrate a step of forming the epitaxial substrate 11 on a compound semiconductor wafer 10. The wafer 10 is made of a semiconductor substrate. Etching stop layers 12 and 14, the p-type contact layer 16, the p-type cladding layer 18, the active layer 20, and the n-type contact layer 22 are epitaxially grown in this order on the wafer 10 by, for example, metal organic vapor phase epitaxy (MOVPE) or molecular beam epitaxy (MBE).

The wafer 10 is a compound semiconductor substrate formed of p-type indium-phosphorus (InP) having a thickness of 350 μm, for example, and is a substrate 11 of 2 inches, for example, as illustrated in FIG. 4A. The above-mentioned compound semiconductor layers are grown on the entire surface of the wafer 10.

The etching stop layer 12 includes undoped gallium indium arsenide (GalnAs), and the etching stop layer 14 includes undoped indium phosphide (InP), for example. The p-type contact layer 16 is formed of, for example, a 100 nm-thick p-type GalnAs layer. The p-type cladding layer 18 is formed of p-type InP having a thickness of, for example, 1800 nm. The p-type layer is doped with zinc (Zn), for example. The active layer 20 has, for example, a multi-quantum well (MQW) structure having a thickness of 90 nm. In the MQW structure, the well layer and the barrier layer of the GaInAsP are stacked by five layers, respectively. The n-type contact layer 22 is formed of, for example, 50 nm-thick n-type InP, and is doped with, for example, silicon (Si).

After the epitaxial growth, the epitaxial substrate 11 is cut along a scribing line 11a indicated by a dotted line in FIG. 4A, thereby forming a plurality of chips 32 from the epitaxial substrate 11. The chip 32 has a rectangular shape, and the length of one side is, for example, 2 mm.

(SOI Substrate)

FIG. 5 to FIG. 6C illustrate a step of preparing the SOI substrate (first substrate) 41. FIG. 6B is a cross-sectional view taken along a line C-C of FIG. 6A, and FIG. 6C is a cross-sectional view taken along a line D-D. The SOI substrate 41 illustrated in FIG. 5 is, for example, an 8-inch wafer, which is a silicon-on-insulator (SOI) substrate including the Si substrate 40, the SiO₂ layer 42, and the Si layer 44, as illustrated in FIG. 6A. The thickness of the substrate 40 is 520 μm, the thickness of the SiO₂ layer 42 is 3 μm, and the thickness of the Si layer is 220 nm.

As illustrated in FIG. 5 to FIG. 6B, a plurality of grooves 47 are formed in the Si layer 44 by dry etching, for example. The portion of the Si layer 44 that is not dry-etched becomes the waveguide mesa 46, the wall 45, and the terrace 48. The grooves 47 are formed on both sides of one waveguide mesa 46, and the terrace 48 is formed on one side of each groove 47. The waveguide mesa 46 and the grooves 47 extend in the same direction. Each groove 47 is provided with a plurality of walls 45. The wall 45 intersects the waveguide mesa 46 and the groove 47, traverses the groove 47 and connects to the waveguide mesa 46 and the terrace 48.

The width of the groove 47 is, for example, 3 μm, and the thickness of the wall 45 is, for example, 1 μm. The distance between the walls 45 is less than the length of the chip 32. As illustrated in FIG. 6B, the walls 45, the waveguide mesas 46 and the terraces 48 have the same height, and their upper faces lie in the same plane. The waveguide mesa 46 has a straight shape in this embodiment, but curved waveguides such as a curved tapered waveguide, a ring resonator, or a DBR may be formed in the Si layer 44.

(Bonding and Subsequent Steps)

FIG. 7A and FIG. 7B are cross-sectional views illustrating a step of bonding, and FIG. 7C is a perspective view illustrating a state after bonding. As illustrated in FIG. 7A, the chips 32 are disposed inside the plurality of openings 62a of the susceptor 100. In placing the chips 32 on the susceptor 100, the chips 32 may be grasped by tweezers, or the chips 32 may be adsorbed and conveyed by collets. The lower face of the chip 32 contacts the surface of the metal plate 60, and the upper face of the chip 32 protrudes from the upper face of the metal plate 62. The lower face of the chip 32 is a back face of the compound semiconductor wafer 10 illustrated in FIG. 4B, the upper face of the chip 32 is the surface of the n-type contact layer 22. The height H1 of the chip 32 is, for example, 0.35 mm. No adhesive is provided between the chip 32 and the metal plate 60, and no adhesive is applied to the upper face of the chip 32.

After disposing the chips 32 on the susceptor 100, the chips 32 are subjected to a plasma-activation process. The chips 32 are irradiated with nitrogen (N₂) plasmas in a vacuum chamber to activate the surfaces of the n-type contact layers 22 to generate dangling bonds. The susceptor 100 is also irradiated with the N₂ plasmas together with the chips 32. The SOI substrate 41 is also irradiated with N₂ plasmas to activate the surfaces of the Si layers 44.

As illustrated in FIG. 7B, the susceptor 100 and the SOI substrate 41 are opposed to each other. The susceptor 100 and the SOI substrate 41 are aligned so that the chip 32 overlaps the waveguide mesas 46. The upper face of the chip 32 is brought into contact with the surface of the SOI substrate 41, the temperature is raised to 150° C. while applying a load, and annealing is performed for 2 hours. As a result, the dangling bonds are bonded to each other, and the chip 32 is bonded to the SOI substrate 41. The chips 32 and the SOI substrate 41 are firmly bonded to each other without using an adhesive because the surfaces activated by the plasma irradiation are in contact with each other. As illustrated in FIG. 7C, the chip 32 overlaps the waveguide mesas 46 and the walls 45.

After the bonding, the compound semiconductor wafer 10 is removed by wet-etching. Then, the mesas 30 are formed from the compound semiconductor layers by dry-etching. The insulating films and the electrodes are formed to form the semiconductor devices 110.

The susceptor 100 according to the first embodiment is a susceptor in which the metal plate 60 and the metal plate 62 are bonded to each other as illustrated in FIG. 1A and FIG. 1B. The surface of the metal plate 60 serves as the bottom surface of the opening 62a. The recess of the susceptor 100 can be manufactured with higher accuracy than a recess formed by countersinking process often used for a carbon susceptor. This is because the metal plates 60 and 62 are formed using polishing having higher accuracy than the countersinking. The variation in thickness (the distance T1 from the bottom surface of the recess of the susceptor 100 to the back face of the susceptor 100) is reduced. Therefore, the chips 32 are disposed on a flat surface, and the variation of the height H1 of the upper surface of the chip 32 becomes small. As a result, the yield in bonding the chip 32 to the SOI substrate 41 is improved.

The thickness and processing accuracy of the metal plate 60 of the susceptor 100 are defined by, for example, the JIS-standard G4304. For example, in the susceptor 100 having a diameter of 50 mm, the thickness variation of the metal plate 60 is 0.003 mm or less, and may be 0.010 mm or less. The height variation among the chips 32 is also reduced to the same degree as the thickness variation, and the yield in the bonding of the chip 32 to the SOI substrate 41 is improved.

The metal plate 60 and the metal plate 62 are joined by metal diffusion bonding, and an adhesive is not used. Even if the susceptor 100 is exposed to a high temperature and a high vacuum during the plasma-activation process, impurities are hardly generated. The chips 32 and the SOI substrate 41 are hard to be contaminated during the plasma-activation. When the impurities originated from an adhesive scatter and stick to the chip 32 or the waveguide mesa 46, the light emitted from the active layer 20 is absorbed by the impurities, and the light output of the semiconductor device 110 (hybrid laser) is lowered. In addition, if impurities stick to the p-type electrode 53, the n-type electrode 55, the p-type wiring 56, or the n-type wiring 58, there is a possibility that an electrical short circuit occurs. By using the susceptor 100 for the bonding step, deterioration of the characteristics of the semiconductor device 110 due to impurities is suppressed.

The metal plate 60 and the metal plate 62 are formed of stainless-steel such as SUS316L (regulated by Japanese Industrial Standards), for example. By polishing stainless steel, variation in thickness can be reduced. Stainless steel is hard to be sputtered by plasma irradiation. In particular, a SUS316L (regulated by Japanese Industrial Standards) containing nickel, chromium, and molybdenum (Ni, Cr, and Mo), which is difficult to be sputtered, is preferably used. Thus, the susceptor 100 is hard to produce impurities due to being sputtered during the plasma-activation process.

The chip 32 and the opening 62a have a square shape, but may have other shapes such as a rectangle, a polygon, and a circle. In order to accommodate the chip 32 in the opening 62a more stably, the inner shape of the opening 62a and the outer shape of the chip 32 preferably have shapes with geometrical similarity. The width W1 of the opening 62a is preferably larger than the width of the chip 32 by about 0.2 mm, for example. So that the chip 32 makes contact with the SOI substrate 41, the height H1 of the chip 32 is larger than the thickness of the metal plate 62. The number of the openings 62a can be changed in accordance with the number of the chips 32 disposed on the susceptor 100.

### Second Embodiment

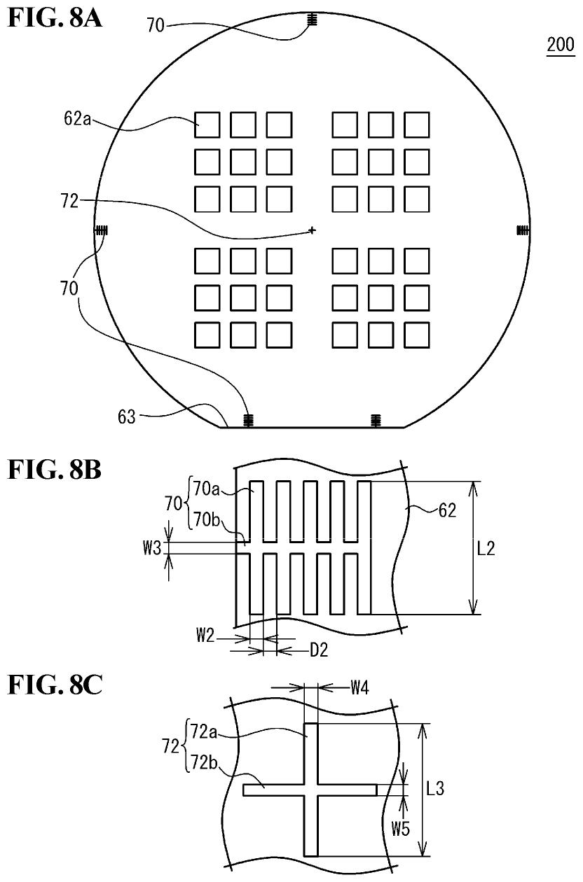

FIG. 8A is a plan view illustrating a susceptor 200 according to the second embodiment, FIG. 8B is an enlarged view of the mark 70, and FIG. 8C is an enlarged view of the mark 72. Description of the similar configuration as that of the first embodiment is omitted.

As illustrated in FIG. 8A, the susceptor 200 has marks 70 and 72. The plurality of marks 70 are provided in the vicinity of the outer periphery of the susceptor 200, and the mark 72 is provided in the center. The marks 70 and 72 are grooves formed on the surface of the metal plate 62. The face on which the marks 70 and 72 are formed is opposite to a face on which the metal plate 60 is bonded. The marks 70 and 72 are formed, for example, by photoetching in the same manner as the opening 62a.

As illustrated in FIG. 8B, the marks 70 include grooves 70a and 70b. One groove 70b extends from the end of the susceptor 200 toward the center. The plurality of grooves 70a are orthogonal to the grooves 70b and are connected to the grooves 70b. The plurality of grooves 70a are separated from each other, and the distance D2 between the grooves 70a is, for example, 0.1 mm. The width W2 of the groove 70a and the width W3 of the groove 70b are 0.1 mm, for example. The length L2 of the mark 70 is, for example, 0.5 mm.

As illustrated in FIG. 8C, the mark 72 has a cross shape, and the width W4 of a groove 72a and the width W5 of a groove 72b, which are formed by the grooves 72a and 72b perpendicular to each other, are, for example, 0.1 mm. The length L3 of the mark 72 is, for example, 0.5 mm.

In the second embodiment, as in the first embodiment, the thickness variation of the metal plate 60 is small. Therefore, the variation in heights of the chips 32 is kept small, and the yield in the bonding of the chip 32 to the SOI substrate 41 is improved.

The marks 70 and 72 are used to align the susceptor 200 and the SOI substrate 41. The plurality of grooves 70a of the mark 70 can be used as a scale. The mark 72 is superimposed on the center of the SOI substrate 41. This improves the accuracy of the alignment and allows the chip 32 to be bonded to a desired location within the SOI substrate 41.

### Third Embodiment

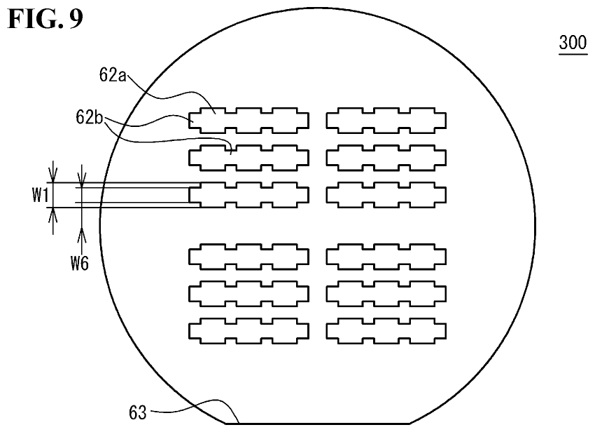

FIG. 9 is a plan view illustrating a susceptor 300 according to a third embodiment. The susceptor 300 has a plurality of openings 62a and 62b. The opening 62b (second opening) is formed in the metal plate 62, and is located on both sides of the opening 62a. The opening 62b has a rectangular shape and is connected to the opening 62a. The plurality of openings 62a and 62b form one oblong opening. The width W6 of the opening 62b is smaller than the width W1 of the opening 62a, and is, for example, 1.5 mm. The other configuration is the same as that of the first embodiment. The opening 62b is formed by photoetching in the same manner as the opening 62a. The susceptor 300 may be provided with the marks 70 and 72 illustrated in FIG. 8A.

According to the third embodiment, as in the first embodiment, the variation in the height of the chip 32 is small. In addition, since the opening 62b is adjacent to the opening 62a, placement and/or removal of the chip 32 into and from the opening 62a are facilitated, and damage of the chip 32 during the placement and/or removal is hard to occur. In particular, when the chip 32 grasped by the tweezers is disposed in the opening 62a, the operation is facilitated by inserting the tweezers into the opening 62b.

### Fourth Embodiment

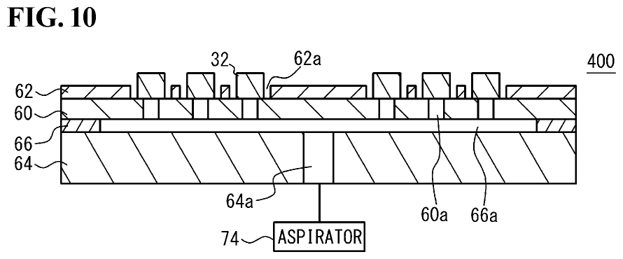

FIG. 10 is a cross-sectional view illustrating a susceptor 400 according to a fourth embodiment. As illustrated in FIG. 10, the susceptor 400 includes metal plates 64, 66, 60, and 62 stacked in order from the bottom. The metal plates are bonded to each other by metal diffusion bonding.

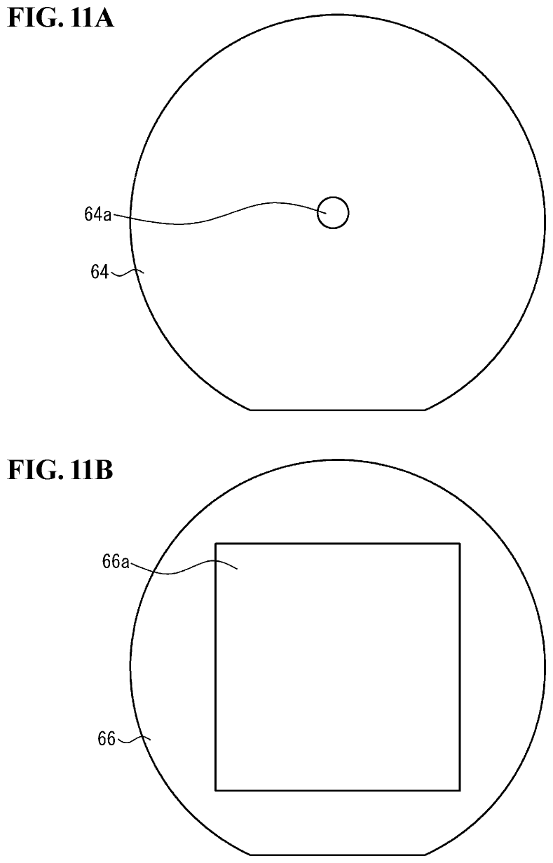

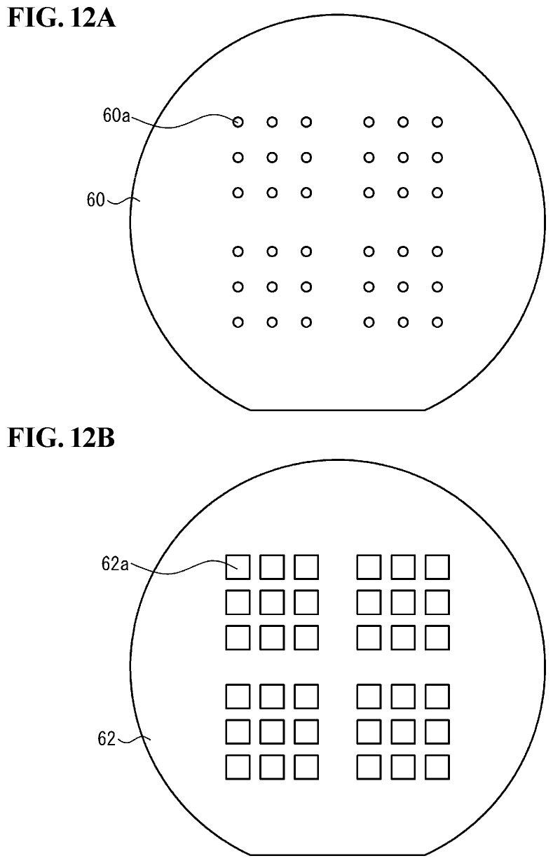

FIG. 11A is a plan view illustrating the metal plate 64, FIG. 11B is a plan view illustrating the metal plate 66, FIG. 12A is a plan view illustrating the metal plate 60, and FIG. 12B is a plan view illustrating the metal plate 62. As illustrated in FIG. 10 and FIG. 11A, the metal plate 64 (third metal plate) has one opening 64a (third opening). The opening 64a is located at the center of the metal plate 64 and penetrates the metal plate 64 in the thickness direction. As illustrated in FIG. 10 and FIG. 11B, the metal plate 66 (third metal plate) has one opening 66a (third opening). The opening 66a has, for example, a rectangular shape, and penetrates the metal plate 66. As illustrated in FIG. 10 and FIG. 12A, the metal plate 60 has a plurality of openings 60a. The opening 60a is circular and penetrates the metal plate 60. As illustrated in FIG. 10 and FIG. 12B, the metal plate 62 has a plurality of openings 62a. The opening 62a penetrates the metal plate 62.

As illustrated in FIG. 10, the opening 62a is larger than the opening 60a, and one opening 62a overlaps one opening 60a. The chip 32 is disposed within the opening 62a and closes the opening 60a. The opening 66a is larger than the openings 60a, 62a, and 64a and overlaps all openings 60a, all openings 62a, and opening 64a. A suction unit (an aspirator) 74 is connected to the opening 64a. The suction unit 74 is a device for suctioning gas, such as a vacuum pump, for example, and suctions the inside of the openings 64a, 66a, 60a, and 62a. As a result, the chip 32 disposed in the opening 62a is attracted to the metal plate 60.

According to the fourth embodiment, the chip 32 can be strongly fixed to the susceptor 400 by attracting the chip 32 through the openings 64a, 66a, and 60a. The strength of fixing the chip 32 to the susceptor 400 can be adjusted by changing the strength of the suction, so that the chip 32 is not broken during being fixed. Therefore, even if ultrasonic cleaning or the like is performed while the chips 32 are mounted on the susceptor 400, for example, positional deviations of the chips 32 are suppressed. After ultrasonic cleaning, the chips 32 can be bonded to the SOI substrate 41 from the susceptor 400. The chips 32 can be released from the susceptor 400 by stopping the suction. The number of openings 60a and 62a may vary depending on the number of chips 32 disposed on the susceptor 400.

Although the embodiments of the present invention have been described above in detail, the present invention is not limited to the specific embodiments, and various modifications and variations are possible within the scope of the gist of the present invention described in the claims.

What is claimed is:

1. A susceptor comprising:
a first metal plate; and
a second metal plate bonded to a surface of the first metal plate,
wherein:
the second metal plate has a plurality of first openings; and
the surface of the first metal plate is exposed from the plurality of first openings.

2. The susceptor according to claim 1, wherein the first metal plate and the second metal plate are bonded through metal diffusion.

3. The susceptor according to claim 1, wherein the first metal plate and the second metal plate are stainless steel plates.

4. The susceptor according to claim 1, wherein thickness variation of the first metal plate is 0.010 mm or less.

5. The susceptor according to claim 1, wherein the second metal plate has a mark on a face opposite to the first metal plate.

6. The susceptor according to claim 1, wherein the second metal plate has a plurality of second openings, each of which is continuous with each of the plurality of first openings.

7. The susceptor according to claim 1, wherein the first metal plate has a plurality of third openings at positions overlapping with the plurality of first openings.

8. A method of manufacturing a semiconductor device comprising:
a step of forming an epitaxial substrate by growing a plurality of compound semiconductor layers on a compound semiconductor substrate;
a step of forming a chip by dividing the epitaxial substrate;
a step of arranging the chip in one of the plurality of first openings of the susceptor according to claim 1;
a step of preparing a first substrate containing silicon, the first substrate having a waveguide mesa; and
a step of bonding the chip to the first substrate by causing the susceptor and the first substrate to face each other.
